(19) United States
(12) Patent Application Publication
(10) Pub. No.: US 2026/0234053 A1
(43) Pub. Date: Aug. 13, 2026

(54) SURFACE-TREATED GLASS CLOTH, PREPREG AND PRINTED WIRING BOARD

(71) Applicants: NITTO BOSEKI CO., LTD., FUKUSHIMA-SHI, FUKUSHIMA (JP); SAIDEN CHEMICAL INDUSTRY CO., LTD., CHUO-KU, TOKYO (JP)

(72) Inventors: Kazutaka ADACHI, FUKUSHIMA-SHI, FUKUSHIMA (JP); Koichi NAKAMURA, FUKUSHIMA-SHI, FUKUSHIMA (JP); Asami SHIRAI, SAITAMA-SHI, SAITAMA (JP); Akira HASEBE, SAITAMA-SHI, SAITAMA (JP)

(21) Appl. No.: 19/157,441

(22) PCT Filed: Jul. 1, 2024
(86) PCT No.: PCT/JP2024/023849

§ 371 Date: Aug. 18, 2025

(30) Foreign Application Priority Data
Jul. 14, 2023 (JP) 2023-115601

(51) Int. Cl. C03C 25/1095; C03C 25/28; C03C 25/40; D03D 15/267; D06M 13/507; D06M 15/233; H05K 1/03

(52) U.S. Cl. CPC C03C 25/1095; C03C 25/28; C03C 25/40; D03D 15/267; D06M 13/507; D06M 15/233; H05K 1/038; D10B 2101/06; D10B 2505/02

(57) ABSTRACT

Provided is a surface-treated glass cloth that is capable of obtaining excellent adhesiveness to a matrix resin, and in which, even when the adhesion amount of a surface treatment layer is increased, the impregnability of the matrix resin to glass fibers is not impaired and excessive hardening of texture does not occur. A surface-treated glass cloth including a surface treatment layer on a surface thereof, wherein the surface treatment layer contains a silane coupling agent and a resin for surface treatment, and the resin for surface treatment contains a structural unit derived from a styrene-based monomer and has an integral value of a proton peak attributed to a benzene ring that falls within a range of 28 to 46% of an integral value of all proton peaks, as measured by ¹H-NMR.

### TECHNICAL FIELD

The present invention relates to a surface-treated glass cloth, a prepreg, and a printed wiring board.

### BACKGROUND ART

In recent years, with the advancement of communication technology, the frequencies used in communication have been shifting towards the GHz band of higher frequencies. However, as the frequency becomes higher, the influence of the dielectric constant and dielectric loss tangent of the materials used in printed wiring boards becomes significant, leading to increased signal attenuation due to dielectric losses.

In the field of communication technology, to reduce the dielectric loss of high-frequency signals, prepreg obtained by impregnating a low dielectric constant and low dielectric loss tangent glass cloth with a low dielectric constant and low dielectric loss tangent matrix resin is used. However, the aforementioned prepreg has a problem of poor adhesiveness between the low dielectric constant and low dielectric loss tangent glass cloth and the low dielectric constant and low dielectric loss tangent matrix resin, leading to a problem such as a decrease in insulation reliability.

Usually, the glass cloth is treated to prepare a surface-treated glass cloth including a surface treatment layer containing a silane coupling agent on its surface to improve compatibility with the matrix resin and obtain excellent adhesiveness. For example, one known surface-treated glass cloth includes a surface treatment layer containing a silane coupling agent and a resin for surface treatment having a functional group capable of generating a chemical bond with a matrix resin on the surface of the glass cloth (see, for example, Patent Literature 1).

According to the surface-treated glass cloth described in Patent Literature 1, by including a surface treatment layer containing the silane coupling agent and the resin for surface treatment having a functional group capable of generating a chemical bond with the matrix resin on the surface of the glass cloth, a printed wiring board with suppressed crack occurrence during machining and decrease in heat resistance to soldering can be obtained.

### CITATION LIST

### Patent Literature

Patent Literature 1: Japanese Patent No. 3897699

### SUMMARY OF INVENTION

### Technical Problem

However, when the adhesion amount of the surface treatment layer in the glass cloth is increased, the adhesiveness to the matrix resin is improved while impregnation of the matrix resin between the glass filaments of the glass fibers constituting the glass cloth becomes difficult, which leads to defects such as striation voids or hardens the texture of the resulting surface-treated glass cloth excessively, causing wrinkles during producing prepreg and deteriorating processability.

The term “striation voids” refers to a state in which the matrix resin hardens before flowing between glass filaments of glass fibers constituting the glass cloth due to low impregnability of the matrix resin to the glass fibers, resulting in the formation of voids without the matrix resin impregnating the glass filaments. For example, when the striation void is present in prepreg, metal constituting the wiring or vias can cause ion migration at the interface between the glass fibers and the matrix resin when manufacturing a printed wiring board using the prepreg, leading to short circuits due to CAF (Conductive Anodic Filament) or the like, resulting in decreased insulation reliability of the printed wiring board.

Thus, an object of the present invention to solve the above problems and to provide a surface-treated glass cloth that is capable of obtaining excellent adhesiveness to a matrix resin and in which, even when the adhesion amount of a surface treatment layer is increased, the impregnability of the matrix resin to glass fibers is not impaired and excessive hardening of texture does not occur.

### Solution to Problem

To achieve the object, the present invention provides a surface-treated glass cloth comprising a surface treatment layer on a surface thereof, wherein the surface treatment layer contains a silane coupling agent and a resin for surface treatment, and the resin for surface treatment contains a structural unit derived from a styrene-based monomer and has an integral value of a proton peak attributed to a benzene ring that falls within a range of 28 to 46% of an integral value of all proton peaks, as measured by ¹H-NMR.

Since the surface treatment layer contains the silane coupling agent and the resin for surface treatment, the surface-treated glass cloth of the present invention is capable of obtaining excellent adhesiveness to a matrix resin, and, even when the adhesion amount of the surface treatment layer is increased, the impregnability of the matrix resin to glass fibers is not impaired and excessive hardening of texture does not occur. As a result, according to the surface-treated glass cloth of the present invention, no defects such as striation voids occur, a prepreg with excellent insulation reliability can be obtained, and excellent processability during manufacturing the prepreg can be achieved.

The phrase “the adhesion amount of a(the) surface treatment layer is increased” means that the adhesion amount of the surface treatment layer is 0.8% by mass or more with respect to the total amount of the surface-treated glass cloth.

When the resin for surface treatment contained in the surface treatment layer has an integral value of a proton peak attributed to a benzene ring that is less than 28% of an integral value of all proton peaks, as measured by ¹H-NMR, the texture of the surface-treated glass cloth of the present invention hardens, and the impregnability of the matrix resin to the glass fibers of the surface-treated glass cloth decreases. Furthermore, when the resin for surface treatment contained in the surface treatment layer has an integral value of a proton peak attributed to a benzene ring that is more than 46% of an integral value of all proton peaks, as measured by ¹H-NMR, the impregnability of the matrix resin to the glass fibers of the surface-treated glass cloth of the present invention decreases.

In the surface-treated glass cloth of the present invention, the silane coupling agent contained in the surface treatment layer is not particularly limited, but is preferably a methacrylic silane when a radical polymerizable thermosetting resin is used as the matrix resin, from the viewpoint of excellent adhesiveness to the radical polymerizable thermosetting resin. Examples of the radical polymerizable thermosetting resin that is used as the matrix resin can include polyphenylene ether, LCP, a cycloolefin polymer, a divinylbenzene resin, and a maleimide resin.

In the surface-treated glass cloth of the present invention, it is preferable that the styrene-based monomer is one or more monomers selected from the styrene-based monomer represented by the following general formula (1)

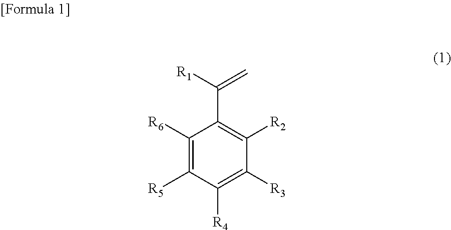

[wherein, R₁ represents hydrogen or an alkyl group having 1 to 2 carbon atoms, and R₂ to R₆ each independently represent hydrogen and a halogen atom, an alkyl group, an alkenyl group, an alkynyl group, or an aryl group, which may contain a heteroatom.]

Specific examples of the styrene-based monomer include styrene, α-methylstyrene, o-methylstyrene, m-methylstyrene, p-methylstyrene, o-ethylstyrene, m-ethylstyrene, p-ethylstyrene, 4-tert-butylstyrene, o-hydroxystyrene, m-hydroxystyrene, p-hydroxystyrene, o-methoxystyrene, m-methoxystyrene, p-methoxystyrene, o-ethoxystyrene, m-ethoxystyrene, p-ethoxystyrene, o-chlorostyrene, m-chlorostyrene, p-chlorostyrene, o-bromostyrene, m-bromostyrene, p-bromostyrene, o-fluorostyrene, m-fluorostyrene, p-fluorostyrene, o-chloromethylstyrene, m-chloromethylstyrene, and p-chloromethylstyrene. Among these, styrene is preferable.

In the surface-treated glass cloth of the present invention, the surface treatment layer may be a single layer containing a mixture of the silane coupling agent and the resin for surface treatment. However, from the viewpoint that the silane coupling agent is excellent in reactivity with glass while the resin for surface treatment is excellent in reactivity with the matrix resin, it is preferable that the surface treatment layer consists of a first surface treatment layer containing the silane coupling agent and a second surface treatment layer containing the resin for surface treatment.

In the surface-treated glass cloth of the present invention, the adhesion amount of the surface treatment layer is preferably in the range of 0.8 to 5.0% by mass with respect to the total amount of the surface-treated glass cloth. When the adhesion amount of the surface treatment layer with respect to the total amount of the surface-treated glass cloth is less than 0.8% by mass, the adhesiveness to the matrix resin may not be sufficient, and when it is more than 5.0% by mass, the surface-treated glass cloth may not be stably produced.

In the surface-treated glass cloth of the present invention, the dielectric loss tangent at a measurement frequency of 10 GHz is preferably in the range of 0.0001 to 0.0040. In the surface-treated glass cloth of the present invention, it is technically difficult to have the dielectric loss tangent of less than 0.0001, and when the dielectric loss tangent is more than 0.0040, it may not be possible to sufficiently reduce the dielectric loss of high-frequency signals when the surface-treated glass cloth of the present invention is used in a prepreg or printed wiring board.

The prepreg and the printed wiring board of present invention includes the surface-treated glass cloth of the present invention.

### DESCRIPTION OF EMBODIMENTS

Next, the embodiments of the present invention will be explained in more detail.

The surface-treated glass cloth of the present embodiments is, for example, a surface-treated glass cloth including a surface treatment layer on a surface of a glass cloth with low dielectric constant and low dielectric loss tangent, wherein the surface treatment layer contains a silane coupling agent and a resin for surface treatment, and the resin for surface treatment contains a structural unit derived from a styrene-based monomer and has an integral value of a proton peak attributed to a benzene ring that falls within a range of 28 to 46% of an integral value of all proton peaks, as measured by ¹H-NMR.

The glass cloth with low dielectric constant and low dielectric loss tangent is a glass fiber fabric woven with glass fiber yarns having a glass composition of low dielectric constant and low dielectric loss tangent as warp and weft yarns. Examples of the glass composition of low dielectric constant and low dielectric loss tangent include silica glass, D glass, NE glass, and L glass. Examples of the glass composition include a composition containing 48.0 to 62.0% by mass SiO₂, 17.0 to 26.0% by mass B₂O₃, 9.0 to 18.0% by mass Al₂O₃, 0.1 to 9.0% by mass CaO, 0 to 6.0% by mass MgO, 0.05 to 0.5% by mass Na₂O, K₂O, and Li₂O in total, 0 to 5.0% by mass TiO₂, 0 to 6.0% by mass SrO, 0 to 3.0% by mass F₂ and Cl₂ in total, and 0 to 6.0% by mass P₂O₅ with respect to the total amount of glass fibers.

The silane coupling agent constituting the surface treatment layer is not particularly limited and examples include an aminosilane, a chlorosilane, an epoxysilane, a mercaptosilane, a vinyl silane, a (meth)acrylic silane, and a cationic silane, preferably a methacrylic silane or a cationic silane, and more preferably a methacrylic silane. Examples of the methacrylic silane include 3-methacryloxypropyltrimethoxysilane. Examples of the cationic silane include N-(vinylbenzyl)-2-aminoethyl-3-aminopropyltrimethoxysilane hydrochloride and N-phenyl-3-aminopropyltrimethoxysilane hydrochloride.

The resin for surface treatment constituting the surface treatment layer contains a structural unit derived from a styrene-based monomer, and it is preferable that the styrene-based monomer is one or more monomers selected from the styrene-based monomer represented by the following general formula (1):

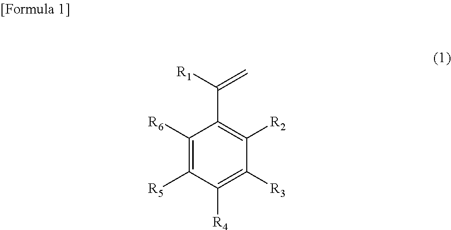

[wherein, R₁ represents hydrogen or an alkyl group having 1 to 2 carbon atoms, and R₂ to R₆ each independently represent hydrogen and a halogen atom, an alkyl group, an alkenyl group, an alkynyl group, or an aryl group, which may contain a heteroatom.]

Examples of the styrene-based monomer include styrene, α-methylstyrene, o-methylstyrene, m-methylstyrene, p-methylstyrene, o-ethylstyrene, m-ethylstyrene, p-ethylstyrene, 4-tert-butylstyrene, o-hydroxystyrene, m-hydroxystyrene, p-hydroxystyrene, o-methoxystyrene, m-methoxystyrene, p-methoxystyrene, o-ethoxystyrene, m-ethoxystyrene, p-ethoxystyrene, o-chlorostyrene, m-chlorostyrene, p-chlorostyrene, o-bromostyrene, m-bromostyrene, p-bromostyrene, o-fluorostyrene, m-fluorostyrene, p-fluorostyrene, o-chloromethylstyrene, m-chloromethylstyrene, and p-chloromethylstyrene.

The resin for surface treatment constituting the surface treatment layer may contain, in addition to the structural unit derived from a styrene-based monomer, a structural unit composed of other polymerizable monomers. The other polymerizable monomers are not particularly limited, but preferably a (meth)acrylic acid ester-based monomer.

Examples of the (meth)acrylic acid ester-based monomer include one or two or more of a (meth)acrylic acid alkyl ester, a (meth)acrylic acid hydroxyalkyl ester, a (meth)acrylic acid alkoxyalkyl ester, a (meth)acrylic acid aralkyl ester, and a (meth)acrylic acid aryl ester, but it is preferable to use a (meth)acrylic acid alkyl ester.

Examples of the (meth)acrylic acid alkyl ester include a linear or branched alkyl group-containing (meth)acrylic acid alkyl ester and an alicyclic (meth)acrylic acid alkyl ester.

Examples of the linear or branched alkyl group-containing (meth)acrylic acid alkyl ester include methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, sec-butyl (meth)acrylate, n-amyl (meth)acrylate, isoamyl (meth)acrylate, n-hexyl (meth)acrylate, n-octyl (meth)acrylate, isooctyl (meth)acrylate, 2-ethylhexyl (meth)acrylate, n-nonyl (meth)acrylate, isononyl (meth)acrylate, n-decyl (meth)acrylate, isodecyl (meth)acrylate, n-undecyl (meth)acrylate, n-dodecyl (meth)acrylate, n-tridecyl (meth)acrylate, n-tetradecyl (meth)acrylate, cetyl (meth)acrylate, stearyl (meth)acrylate, and behenyl (meth)acrylate.

Examples of the alicyclic (meth)acrylic acid alkyl ester include cyclohexyl (meth)acrylate, 4-tert-butylcyclohexyl (meth)acrylate, isobornyl (meth)acrylate, dicyclopentanyl (meth)acrylate, and dicyclopentenyl (meth)acrylate.

As the other resin components, one or two or more of the (meth)acrylic acid alkyl esters can be used, but preferably, a linear or branched alkyl group-containing (meth)acrylic acid alkyl ester having 1 to 18 carbon atoms, more preferably 1 to 12 carbon atoms, can be used. Examples of the (meth)acrylic acid alkyl ester include methyl (meth)acrylate or 2-ethylhexyl (meth)acrylate.

The resin for surface treatment is preferably an emulsion resin of a polymer of the styrene-based monomer and another polymerizable monomer. Examples of the emulsion resin include an emulsion resin obtained by mixing one or two or more emulsion resins of a polymer of the styrene-based monomer and another polymerizable monomer, and an emulsion resin obtained by mixing a styrene resin and an acrylic resin.

The emulsion resin can be obtained by polymerizing one or two or more polymerizable monomer components that form resin particles in an aqueous medium such as water that is normally contained in the emulsion resin, or by re-emulsifying resin particles produced separately from an aqueous medium by methods such as forced emulsification or self-emulsification, but it is preferable that the emulsion resin is obtained by emulsion polymerization of polymerizable monomer components that form resin particles in an aqueous medium.

The aqueous medium is preferably water, and water alone may be used or a mixed medium of water and an organic solvent may be used. Examples of the organic solvent include, but are not limited to, methanol, ethanol, isopropanol, diethyleneglycol monoethyl ether, and N-methyl-pyrrolidone. The organic solvents may be used alone or in combination of two or more. The resin constituting the emulsion resin can be uniformly coated on the surface of glass fibers in the step of forming a surface treatment layer on the glass cloth mentioned below. From the viewpoint of spreading the emulsion resin uniformly, it is preferable that resin has a glass transition temperature in the range of 20 to 60° C., more preferably a glass transition temperature in the range of 25 to 55° C.

When the resin for surface treatment has an integral value of a proton peak attributed to a benzene ring that falls within a range of 28 to 46% of an integral value of all proton peaks, as measured by ¹H-NMR, the surface-treated glass cloth of the present embodiments including a surface treatment layer containing the resin for surface treatment along with the silane coupling agent can provide an excellent adhesiveness between the glass fibers and a matrix resin, and even when the adhesion amount of the surface treatment layer is increased, the impregnability of the matrix resin to glass fibers of the surface-treated glass cloth is not impaired and excessive hardening of texture of the surface-treated glass cloth does not occur, thus excellent processability during manufacturing prepreg can be achieved.

When the resin for surface treatment has an integral value of a proton peak attributed to a benzene ring that is less than 28% with respect the an integral value of all proton peaks, as measured by ¹H-NMR, the surface-treated glass cloth of the present embodiments including a surface treatment layer containing the resin for surface treatment along with the silane coupling agent has a stiff texture, and an impaired impregnability of the matrix resin to glass fibers of the surface-treated glass cloth. When the resin for surface treatment has an integral value of a proton peak attributed to a benzene ring that is more than 46% of the integral value of all proton peaks, as measured by ¹H-NMR, the surface-treated glass cloth of the present embodiments including a surface treatment layer containing the resin for surface treatment along with the silane coupling agent has an impaired impregnability of the matrix resin to glass fibers of the surface-treated glass cloth.

The measurement by ¹H-NMR can be performed, for example, using a nuclear magnetic resonance analyzer manufactured by OXFORD INSTRUMENTS plc. (product name: Pulsar HFC), with a solvent of chloroform-D1 (CDCl₃) containing tetramethylsilane (TMS) as an internal standard, and using a solution obtained by dissolving the resin for surface treatment in the solvent at a concentration of 0.1 to 10% by mass as a sample. From results of the measurement by ¹H-NMR, peaks in the range of chemical shift 66.3 to 7.2 ppm relative to the peak of the internal standard are assigned to the proton peaks attributed to the benzene ring, and then the proportion of the integral value of the proton peaks attributed to the benzene ring to the integral value of all proton peaks excluding the peaks of the internal standard and peaks of chloroform (CHCl₃) slightly contained in chloroform-D1 is calculated.

In the surface-treated glass cloth of the present embodiments, the surface treatment layer may be a single layer containing a mixture of the silane coupling agent and the resin for surface treatment. However, from the viewpoint that the silane coupling agent is excellent in reactivity with glass while the resin for surface treatment is excellent in reactivity with the matrix resin, it is preferable that the surface treatment layer consists of a first surface treatment layer containing the silane coupling agent and a second surface treatment layer containing the resin for surface treatment.

The adhesion amount of the surface treatment layer on the glass cloth is preferably in the range of 0.8 to 5.0% by mass with respect to the total amount of the surface-treated glass cloth. When the adhesion amount of the surface treatment layer with respect to the total amount of the surface-treated glass cloth is less than 0.8% by mass, the adhesiveness to the matrix resin may not be sufficient, and when the adhesion amount of the surface treatment layer with respect to the total amount of the surface-treated glass cloth is more than 5.0% by mass, the surface-treated glass cloth may not be stably produced. From the viewpoints of the adhesiveness to the matrix resin and production stability, the adhesion amount of the surface treatment layer is more preferably in the range of 1.0 to 3.0% by mass, and further preferably in the range of 1.2 to 2.0% by mass.

In the surface-treated glass cloth of the present embodiments, it is preferable that the dielectric loss tangent at a measurement frequency of 10 GHz is in the range of 0.0001 to 0.0040. In the surface-treated glass cloth of the present invention, it is technically difficult to have the dielectric loss tangent of less than 0.0001, and when the dielectric loss tangent is more than 0.0040, it may not be possible to sufficiently reduce the dielectric loss of high-frequency signals when the surface-treated glass cloth of the present invention is used in a prepreg or printed wiring board. From the viewpoints of productivity and workability of glass fibers, it is more preferable that the dielectric loss tangent is in the range of 0.0008 to 0.0030.

The surface-treated glass cloth of the present embodiments can be produced, for example, as follows.

First, glass raw materials that are formulated to be a glass composition for glass fibers having a predetermined glass composition are melted in a glass melting furnace to produce molten glass (a melt of glass composition for glass fibers). Examples of the glass composition include a glass composition of low dielectric constant and low dielectric loss tangent describe above.

Regarding the measurement of the content of each component of the glass composition, Li that is a light element can be measured using an ICP optical emission spectrometer and other elements can be measured using a wavelength dispersive X-ray fluorescence analyzer. Specifically, the measurement of the content of each component of the glass composition can be performed as follows.

First, glass fibers are cut into an appropriate size, then placed in a platinum crucible, and melt at a temperature of 1550° C. in an electric furnace for 6 hours with stirring to obtain homogeneous molten glass. When organic substances are adhered to the surface of the glass fibers or the glass fibers are contained in an organic substance (a resin) mainly as a reinforcing material, the organic substances are removed in advance, for example, by heating in a muffle furnace at 300 to 650° C. for about 2 to 24 hours.

Next, the obtained molten glass is poured onto a carbon plate to prepare a glass cullet, which is then crushed and pulverized to make glass powder. For the light element Li, the glass powder is decomposed with an acid, and then quantitatively analyzed using an ICP optical emission spectrometer. For the other elements, the glass powder is formed into a disc shape with a pressing machine and then quantitatively analyzed using a wavelength dispersive X-ray fluorescence analyzer. By converting these quantitative analysis results into oxide equivalents, and calculating the content of each component and their total amount, the content (% by mass) of each component described above can be determined from these values.

Next, the molten glass is extruded from a container (bushing) having a nozzle plate in which several to several thousand nozzle tips are formed, stretched by high-speed winding while cooled, and solidified into a fibrous shape (this process is sometimes referred to as “spinning”) to form glass filaments. The bushing is made, for example, from a precious metal such as platinum.

The glass filament formed by extrusion from a single nozzle tip or hole followed by cooling and solidification typically possesses a circular cross-section and has a diameter of 3.0 to 10 μm. On the other hand, when the nozzle tip is non-circular in shape and has protrusions or indentations that rapidly cool the molten glass, a glass filament with a non-circular (e.g. elliptical or long-oval) cross-section can be obtained by controlling the temperature conditions.

Next, a binder (also known as a primary sizing agent) is applied to 20 to 300 glass filaments formed as described above with an applicator to consolidate them, and the consolidated filaments are then wound around a collet to form glass strands (bundles of glass fibers).

Then, the glass strands formed are used as warp yarn glass strands and weft yarn glass strands, and weaving is performed using the warp yarn glass strands as warp yarns and the weft yarn glass strands as weft yarns to obtain a glass cloth. The weaving can be done by a known loom, and examples of the loom include a jet loom such as air-jet or water-jet, a shuttle loom, and a rapier loom. Examples of the weave with the loom include plain weave, satin weave, matt weave, and twill weave, and the plain weave is preferable from the viewpoint of efficient manufacturing.

Next, the glass cloth is subjected to a degreasing treatment, a surface treatment, or a fiber opening treatment to obtain the surface-treated glass cloth of the present embodiments. The order of the degreasing treatment, the surface treatment, or the fiber opening treatment is not particularly limited, and for example, the fiber opening treatment, the degreasing treatment, and the surface treatment can be applied in this order.

Examples of the fiber opening treatment include a treatment including applying a tension in the range of 30 to 200 N to the warp yarn of the glass cloth, and performing fiber opening such as fiber opening by water flow pressure, fiber opening by high-frequency vibration using a liquid as a medium, fiber opening by pressure of a fluid with surface pressure, or fiber opening by pressurization with rolls, to widen the yarn width of the warp and weft yarns.

The degreasing treatment includes placing the glass cloth after the fiber opening treatment in a heating furnace with an ambient temperature in the range of 350 to 400° C. for a period of 32 to 75 hours to thermally decompose the binder adhered to the glass cloth.

The surface treatment first includes immersing the glass cloth after the degreasing treatment in a silane coupling agent treatment solution containing a silane coupling agent at a concentration in the range of 0.3 to 4.0% by mass, then squeezing out excess water, and heating and drying the glass cloth at a temperature in the range of 80 to 180° C. for a period of 1 to 30 minutes to form a first surface treatment layer. The glass cloth with the first surface treatment layer is then immersed in a resin composition treatment solution for surface treatment containing a resin for surface treatment that contains a structural unit derived from a styrene-based monomer and has an integral value of a proton peak attributed to a benzene ring that falls within a range of 28 to 46% of an integral value of all proton peaks, as measured by ¹H-NMR, at a concentration in a range of 3 to 20% by mass, and excess water is squeezed out, and then the glass cloth is heated and dried at a temperature in the range of 80 to 180° C. for a period of 1 to 30 minutes to form a second surface treatment layer on the first surface treatment layer.

The silane coupling agent treatment solution contains, for example, the silane coupling agent, an organic acid, and a surfactant.

Examples of the silane coupling agent include a methacrylic silane such as 3-methacryloxypropyltrimethoxysilane, or a cationic silane such as N-(vinylbenzyl)-2-aminoethyl-3-aminopropyltrimethoxysilane hydrochloride and N-phenyl-3-aminopropyltrimethoxysilane hydrochloride.

Examples of the organic acid include acetic acid, formic acid, propionic acid, malonic acid, maleic acid, succinic acid, oxalic acid, malic acid, and citric acid, but in view of the excellent handleability, acetic acid is preferable.

Examples of the surfactant include a nonionic surfactant, a cationic surfactant, an anionic surfactant, and an amphoteric surfactant. In the present embodiments, the surfactant can be used alone or in combination of two or more.

Examples of the nonionic surfactant include an ethylene oxide-propylene oxide alkyl ether, a polyoxyethylene alkyl ether, a polyoxyethylene-polyoxypropylene block copolymer, an alkyl polyoxyethylene-polyoxypropylene block copolymer ether, a polyoxyethylene fatty acid ester, a polyoxyethylene fatty acid monoester, a polyoxyethylene fatty acid diester, a polyoxyethylene sorbitan fatty acid ester, a glycerol fatty acid ester ethylene oxide adduct, a polyoxyethylene castor oil ether, a hydrogenated castor oil ethylene oxide adduct, an alkyl amine ethylene oxide adduct, a fatty acid amide ethylene oxide adduct, a glycerol fatty acid ester, a polyglycerol fatty acid ester, a pentaerythritol fatty acid ester, a sorbitol fatty acid ester, a sorbitan fatty acid ester, a sucrose fatty acid ester, a polyol alkyl ether, a fatty acid alkanolamide, an acetyleneglycol, an acetylen alcohol, an acetyleneglycol ethylene oxide adduct, and an acetylen alcohol ethylene oxide adduct.

Examples of the cationic surfactant include an alkyl dimethyl benzyl ammonium chloride, an alkyl trimethyl ammonium chloride, an alkyl dimethyl ethyl ammonium ethyl sulfate, a higher alkyl amine salt, an ethylene oxide adduct to a higher alkyl amine, a condensate of a higher fatty acid and a polyalkylene polyamine, an ester salt of a higher fatty acid and an alkanol amine, a salt of a higher fatty acid amide, an imidazolinium-type cationic surfactant, and an alkyl pyridinium salt. Examples of the higher alkyl amine salt include an acetate salt and a hydrochloride salt.

Examples of the anionic surfactant include a higher alcohol sulfate ester, a higher alkyl ether sulfate ester, an α-olefin sulfonate ester, an alkyl benzene sulfonate salt, an α-olefin sulfonate salt, a reaction product of a fatty acid halide with N-methyltaurine, a sulfosuccinic acid dialkyl ester salt, a higher alcohol phosphate ester salt, and a phosphate ester salt of a higher alcohol ethylene oxide adduct.

Examples of the amphoteric surfactant include an amino acid-type amphoteric surfactant, a betaine-type amphoteric surfactant, and an imidazoline-type amphoteric surfactant. Examples of the amino acid-type amphoteric surfactant include an alkylaminopropionic acid alkali metal salt. Examples of the betaine-type amphoteric surfactant include an alkyl dimethyl betaine.

The resin composition treatment solution for surface treatment is a solution obtained by diluting the emulsion resin that contains a structural unit derived from a styrene-based monomer to a range of 3 to 20% by mass. Examples of the emulsion resin include a styrene-containing acrylic resin, a styrene-butadiene resin, and an acrylonitrile-butadiene-styrene copolymer resin (ABS resin).

As a result, it is possible to obtain the surface-treated glass cloth of the present embodiments in which the dielectric loss tangent at a measurement frequency of 10 GHz is in the range of 0.0001 to 0.0040.

The prepreg of the present embodiments contains the surface-treated glass cloth of the present embodiments and a matrix resin impregnated in the surface-treated glass cloth. The matrix resin may be any type of resin and is not particularly limited as long as it is used as a matrix resin in a prepreg. However, the surface-treated glass cloth of the present embodiments can be particularly advantageously used when the matrix resin is a resin with low dielectric constant and low dielectric loss tangent. Examples of the resin with low dielectric constant and low dielectric loss tangent include polyphenylene ether, LCP, a cycloolefin polymer, a divinylbenzene resin, and a maleimide resin.

The prepreg of the present embodiments can be produced by immersing the surface-treated glass cloth of the present embodiments in a varnish containing the matrix resin and preliminarily drying it at a temperature in the range of 110 to 160° C. for a period of 5 to 20 minutes.

The printed wiring board of the present embodiments can be obtained, for example, by curing the prepreg of the present embodiments described above.

Next, Examples and Comparative Examples of the present invention are shown.

### EXAMPLES

### Example 1

In this Example, glass fibers with low dielectric constant and low dielectric loss tangent having a filament diameter of 7 μm and a yarn weight of 20.8 g/1000 m were used to weave a glass cloth of IPC 4412 specification #2116 (warp yarn density of 59 threads/25 mm, weft yarn density of 57 threads/25 mm, basis weight (weight per unit area) of 95 g/m²). The dielectric constant of the glass fiber at the measurement frequency of 10 GHz was 4.7 and the dielectric loss tangent thereof was 0.0025. The glass composition of the glass fibers contained 54.5% by mass of SiO₂, 19.4% by mass of B₂O₃, 14.6% by mass of Al₂O₃, 4.2% by mass of MgO, 4.1% by mass of CaO, 1.9% by mass of TiO₂, 0.1% by mass of Fe₂O₃, 0.2% by mass of Li₂O, Na₂O, and K₂O in total, and 1.0% by mass of F₂ with respect to the total amount of glass fibers. In tables 1 and 2, the glass composition is described as “low dielectric glass”.

Next, the glass cloth obtained after weaving was subjected to fiber opening treatment with high-pressure water flow at 40° C. with a pressure of 2 MPa, followed by heating at 410° C. for 36 hours for degreasing treatment, thereby preparing a glass cloth for surface treatment.

Next, the glass cloth after degreasing was immersed in a silane coupling agent treatment solution, squeezed to remove excess water, and then heated and dried at a temperature of 110° C. for 5 minutes to form a first surface treatment layer on the surface of the glass cloth. Then, the glass cloth with the first surface treatment layer was immersed in a styrene-based emulsion resin treatment solution, squeezed to remove excess water, and then heated and dried at a temperature of 110° C. for 5 minutes to form a second surface treatment layer, thereby obtaining a surface-treated glass cloth. The surface-treated glass cloth included a surface treatment layer consisting of a first surface treatment layer and a second surface treatment layer on the surface of the glass cloth, in which the second surface treatment layer was formed on the first surface treatment layer.

The silane coupling agent treatment solution was prepared in an amount of 2 liters by using 3-methacryloxypropyltrimethoxysilane (manufactured by Dow Toray Co., Ltd.) as a silane coupling agent, mixing the silane coupling agent in water to have a composition of 1.0% by mass solid content, 0.1% by mass acetic acid, and 0.05% by mass surfactant (polyoxyethylene alkyl ether), and stirring the mixture for 1 hour with a magnetic stirrer.

The styrene-based emulsion resin treatment solution was prepared in an amount of 2 liters by diluting an emulsion obtained by polymerizing a styrene-based monomer (styrene) and (meth)acrylic ester-based monomers (2-ethylhexyl acrylate and methyl methacrylate) in a mass ratio of 75:25 with water to 10% by mass. The styrene-based emulsion resin was synthesized by known emulsion polymerization (for example, by the method described in paragraph 0091 (Manufacturing Example 1) of Japanese Patent No. 7217481), but the synthesis method is not limited to this, and the styrene-based emulsion resin may also be synthesized by known solution polymerization, bulk polymerization, suspension polymerization, or the like. The ratio of 2-ethylhexyl acrylate to methyl methacrylate in the styrene-based emulsion resin was adjusted to obtain the desired Tg.

The styrene-based emulsion resin mentioned above was a copolymer resin of a styrene-based monomer and a (meth)acrylic acid ester-based monomer, having a styrene composition content ratio of 75% by mass and a glass transition temperature (Tg) of 35° C.

Next, the surface-treated glass cloth was cut into a size of 350 mm×400 mm to prepare surface-treated glass cloth pieces, which were immersed in a polyphenylene ether resin varnish and preliminarily dried for 10 minutes at a temperature of 150° C. to prepare prepreg.

The aforementioned polyphenylene ether resin varnish contained 450 parts by mass of toluene (manufactured by MITSUBISHI GAS CHEMICAL COMPANY, INC., product name: OPE-2St), 100 parts by mass of triallyl isocyanurate (manufactured by Evonik Industries AG, product name: TAICROS), 4 parts by mass of 1,3-di(t-butylperoxyisopropyl)benzene (manufactured by NOF CORPORATION, product name: Parbutyl P), and 250 parts by mass of toluene (manufactured by FUJIFILM Wako Pure Chemical Corporation). It should be noted that the triallylisocyanurate acts as a crosslinking agent.

Next, four sheets of the prepreg were laminated and sandwiched between cellophane films, and subjected to heating and pressing in a vacuum hot press (manufactured by KITAGAWA SEIKI CO., LTD.) at a temperature of 205° C. and a pressure of 18 kgf/cm² for one hour in a vacuum to prepare a laminated board with a thickness of about 0.3 mm as a simulated printed wiring board.

Next, the surface-treated glass cloth obtained in this Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks, as measured by ¹H-NMR (proportion of peak derived from benzene ring to total integral value as measured by ¹H-NMR), the texture, and the impregnability of the matrix resin by the following methods, and the processability was evaluated by the following method. Furthermore, the laminated board obtained in this Example was measured for the whitening distance by the following method. The results are shown in Table 1.

In Table 1, 3-methacryloxypropyltrimethoxysilane is referred to as “methacryl”, and the type of emulsion resin containing a copolymer resin of a styrene-based monomer and a (meth)acrylic acid ester-based monomer is referred to as “styrene/acryl”.

### [Measurement Method for Adhesion Amount]

First, the mass of a crucible is measured in accordance with JIS R 3420 and set to m0. Next, a surface-treated glass cloth test piece having a size of 30 cm in the longitudinal direction and 20 cm in the width direction is placed in the crucible, and heated for 60 minutes in a dryer heated to 110° C. to dry the surface-treated glass cloth test piece. After drying, the crucible and the surface-treated glass cloth test piece are put into a desiccator and cooled for 30 minutes. After cooling, the mass of the crucible and the surface-treated glass cloth test piece is measured and set to m1. Next, the crucible and the surface-treated glass cloth test piece are placed in a muffle furnace heated to 625° C. and incinerated for 30 minutes. After incineration, the crucible and the surface-treated glass cloth test piece are put into a desiccator and cooled for 90 minutes. After cooling, the mass of the crucible and the surface-treated glass cloth test piece is measured and set to m2. Next, the adhesion amount is calculated by the following equation.

$$Adhesion amount ( \% by mass ) = ( m 1 - m 2 ) / ( m 1 - m 0 ) \times 100$$

### [Calculation Method of Glass Transition Temperature (Tg)]

Tg of the copolymer resin is calculated as a theoretical value using Tg of a homopolymer determined by DSC measurement according to the following FOX equation.

$$1 / Tg = {W}_{1} / {Tg}_{1} + {W}_{2} / {Tg}_{2} + … + {W}_{n} / {Tg}_{n}$$

In the equation, Tg represents the glass transition temperature (unit: K) of polymer (copolymer) composed of n types of monomer components (monomers 1 to n). W₁, W₂, . . . , Wₙ represent the mass fraction of each monomer (1, 2, . . . , n) with respect to the total amount of the n types of monomer components, and Tg₁, Tg₂, . . . , Tgₙ represent the glass transition temperature (unit: K) of homopolymer of each monomer (1, 2, . . . , n). The following numerical values are used as the glass transition temperatures of the homopolymer of the monomer described above.
Styrene: 100° C.,
2-Ethylhexyl acrylate: −70° C.
Methyl methacrylate: 105° C.
   [Method for Measuring Proportion of Peak Derived from Benzene Ring to Total Integral Value as Measured by ¹H-NMR]

The surface-treated glass cloth cut into a size of 10 cm×10 cm is immersed in 30 mL of toluene (manufactured by JUNSEI CHEMICAL CO., LTD., special grade reagent) for 5 minutes, and then washed. The washing solution is subjected to an evaporator to completely evaporate the toluene. The residual components are dissolved in chloroform-D1 containing tetramethylsilane (TMS) as an internal standard (Sigma-Aldrich; 0.03 vol. % TMS, deuteration degree min. 99.8% for NMR spectroscopy (stabilized with silver)), and measured by ¹H-NMR with a nuclear magnetic resonance analyzer (product name: Pulsar HFC, 60 MHz) manufactured by OXFORD INSTRUMENTS plc. At least 20 accumulations are performed, and the peak of TMS is set to 0.0 ppm. Then, the value obtained by dividing the integral value of the peaks of which the peak top exists in the range of 6.3 to 7.2 ppm by the integral value of all peaks excluding the peak of TMS (peak at 0.0 ppm) and the peak of chloroform (CHCl₃) slightly contained in chloroform-D1 (peak near 73.3 ppm), and multiplying by 100 is set to the proportion of the proton peaks attributed to the benzene ring to the integral value of all proton peaks.

### [Measurement Method for Texture]

The surface-treated glass cloth is cut into a size of 3 cm in width and 17 cm in length to prepare test pieces. Then, the test piece is fixed at a point 3 cm inside from the edge of a flat platform with dimensions of 5.5 cm×3.5 cm placed horizontally at a height of 25 cm above the ground, and let the remaining 14 cm hang outside the platform, and the height at which the surface-treated glass cloth hangs vertically is measured. The larger the value, the softer the texture, and the smaller the value, the harder the texture.

### [Measurement Method for Impregnability]

The surface-treated glass cloth is cut into a size of 60 mm×40 mm centered at three points of a point 200 mm inside from one end, a point 200 mm inside from another end, and the center point in the width direction of the surface-treated glass cloth to prepare test pieces for impregnability evaluation. The test piece for impregnability evaluation is immersed in benzyl alcohol, and the time until benzyl alcohol completely permeates the glass cloth piece for impregnability evaluation starting from immediately after immersion is measured in the warp direction. For each measurement point, five glass cloth pieces for impregnability evaluation are measured, and the average value for each measurement point is calculated.

### [Measurement Method for Whitening Distance]

A laminated board is cut into a size of 7 cm×4 cm using an NC router, and slits of 2 cm are made in each of the warp and weft directions to prepare a test piece. A 1 mol/L NaOH (manufactured by FUJIFILM Wako Pure Chemical Corporation) aqueous solution is prepared in a beaker and heated to 60° C. The test piece is immersed in the NaOH aqueous solution for 30 hours, and the distance of whitening due to delamination of the resin and glass interface in the warp and weft directions is measured at 100 times magnification using a digital microscope (manufactured by KEYENCE CORPORATION). The distance is measured at 24 points in each of the warp and weft directions, and the average value of the measured values is calculated and defined as the whitening distance. The whitening distance due to the delamination is correlated with the insulation reliability of the printed wiring board, and the shorter the whitening distance, the higher the insulation reliability.

The value obtained by dividing each measured value of Examples 1 to 5 and Comparative Examples 1 to 7 by the measured value of Reference Example 1 mentioned below, and the value obtained by dividing the measured value of Example 6 by the measured value of Reference Example 2 mentioned below were used as indices relative to the Reference Examples. The index relative to the Reference Example indicates the improvement index of the whitening distance from the Reference Example.

### [Evaluation Method for Processability]

On the production line from the heating and drying process after forming the second surface treatment layer of the surface-treated glass cloth to the winding of the surface-treated glass cloth, the case where no wrinkles occur is rated as “O”, the case where wrinkles occur without leaving marks is rated as “A”, and the case where wrinkles that leave marks occur is rated as “x”.

### Reference Example 1

In this Reference Example, a surface-treated glass cloth and a laminated board were obtained in exactly the same manner as in Example 1 except for not applying a treatment of immersing the glass cloth in the emulsion resin treatment solution at the surface treatment of the glass cloth.

Next, the surface-treated glass cloth obtained in this Reference Example was measured or calculated for the adhesion amount of the surface treatment layer, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Reference Example was measured for the whitening distance in exactly the same manner as in Example 1. The results are shown in Table 1.

### Example 2

In this Example 2, a surface-treated glass cloth and a laminated board were obtained in exactly the same manner as in Example 1 except for using a styrene-based emulsion resin of a copolymer of styrene and butadiene (manufactured by ENEOS Corporation, product name: SBL 0597C) as the styrene-based emulsion resin. Since the styrene-based emulsion resin used in this Example was a commercial product, the content ratio of styrene composition in the copolymer resin contained was not known.

Next, the surface-treated glass cloth obtained in this Example was measured for the adhesion amount of the surface treatment layer, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. The glass transition temperature (Tg) of the emulsion resin shown is the catalog value. Furthermore, the laminated board obtained in this Example was measured for the whitening distance in exactly the same manner as in Example 1. The results are shown in Table 1.

In Table 1, the type of emulsion resin containing a copolymer resin of styrene and butadiene is described as “styrene/butadiene”.

### Example 3

In this Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 70:30.

Next, the surface-treated glass cloth obtained in this Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Example was measured for the whitening distance in exactly the same manner as in Example 1. The results are shown in Table 1.

### Example 4

In this Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 74:26.

Next, the surface-treated glass cloth obtained in this Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Example was measured for the whitening distance in exactly the same manner as in Example 1. The results are shown in Table 1.

### Example 5

In this Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 81:19.

Next, the surface-treated glass cloth obtained in this Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Example was measured for the whitening distance in exactly the same manner as in Example 1. The results are shown in Table 1.

### Example 6

In this Example, a surface-treated glass cloth and a laminated board were obtained in exactly the same manner as in Example 1 except for using N-(vinylbenzyl)-2-aminoethyl-3-aminopropyltrimethoxysilane hydrochloride as the silane coupling agent.

Next, the surface-treated glass cloth obtained in this Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Example was measured for the whitening distance in exactly the same manner as in Example 1. Regarding the whitening distance in this Example, the value obtained by dividing the measured value of this Example by the measured value of Reference Example 2 mentioned below was used as the index relative to the Reference Example. The results are shown in Table 1.

In Table 1, N-(vinylbenzyl)-2-aminoethyl-3-aminopropyltrimethoxysilane hydrochloride is referred to as “cationic”.

### Reference Example 2

In this Reference Example, a surface-treated glass cloth and a laminated board were obtained in exactly the same manner as in Example 6 except for not applying a treatment of immersing the glass cloth in the emulsion resin treatment solution at the surface treatment of the glass cloth.

Next, the surface-treated glass cloth obtained in this Reference Example was measured or calculated for the adhesion amount of the surface treatment layer, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Reference Example was measured for the whitening distance in exactly the same manner as in Example 1. The results are shown in Table 1.

### Comparative Example 1

In this Comparative Example, a surface-treated glass cloth and a laminated board were obtained in exactly the same manner as in Example 1 except for using an emulsion resin treatment solution containing a copolymer resin of acrylic resins (2-ethylhexyl acrylate and methyl methacrylate). The emulsion resin does not contain a structural unit derived from a styrene-based monomer.

Next, the surface-treated glass cloth obtained in this Comparative Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

In Table 2, 3-methacryloxypropyltrimethoxysilane is referred to as “methacryl”, and the type of emulsion resin containing a polymer resin of the (meth)acrylic acid ester-based monomer is referred to as “acryl”.

### Comparative Example 2

In this Comparative Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 40:60.

Next, the surface-treated glass cloth obtained in this Comparative Example was measured or calculated for the adhesion amount of the surface treatment layer, the glass transition temperature (Tg) of the emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

In Table 2, the type of emulsion resin containing a copolymer resin of a styrene-based monomer and a (meth)acrylic acid ester-based monomer is referred to as “styrene/acryl”.

### Comparative Example 3

In this Comparative Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 54:46.

Next, the surface-treated glass cloth obtained in this Comparative Example was measured or calculated for the adhesion amount of the surface treatment layer, the glass transition temperature (Tg) of the styrene-based emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

### Comparative Example 4

In this Comparative Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 93:7.

Next, the surface-treated glass cloth obtained in this Comparative Example was measured or calculated for the adhesion amount of the surface treatment layer, the glass transition temperature (Tg) of the styrene-based emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

### Comparative Example 5

In this Comparative Example, a surface-treated glass cloth and a laminated board were obtained in exactly the same manner as in Example 1 except for using a styrene-based emulsion resin treatment solution obtained by polymerizing a styrene-based monomer (styrene) and (meth)acrylic ester-based monomers (2-ethylhexyl acrylate and methyl methacrylate) in a mass ratio of 88:12.

Next, the surface-treated glass cloth obtained in this Comparative Example was measured or calculated for the adhesion amount of the surface treatment layer, the glass transition temperature (Tg) of the styrene-based emulsion resin, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

### Comparative Example 6

In this Comparative Example, a surface-treated glass cloth and a laminated board were obtained in exactly the same manner as in Example 1 except for setting the solid content of the silane coupling agent in the silane coupling agent treatment solution to 10.0% by mass in the surface treatment of the glass cloth and not applying a treatment of immersing the glass cloth in the emulsion resin treatment solution. In this Comparative Example, as the result of setting the solid content of the silane coupling agent in the silane coupling agent treatment solution to 10.0% by mass, the adhesion amount of the surface treatment layer was increased compared to that in Example 1.

Next, the surface-treated glass cloth obtained in this Comparative Example was measured or calculated for the adhesion amount of the surface treatment layer, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

### Comparative Example 7

In this Comparative Example, a surface-treated glass cloth and a laminated board were obtained in exactly the same manner as in Example 1 except for setting the solid content of the silane coupling agent in the silane coupling agent treatment solution to 20.0% by mass in the surface treatment of the glass cloth and not applying a treatment of immersing the glass cloth in the emulsion resin treatment solution. In this Comparative Example, as the result of setting the solid content of the silane coupling agent in the silane coupling agent treatment solution to 20.0% by mass, the adhesion amount of the surface treatment layer was increased compared to that in Example 1.

Next, the surface-treated glass cloth obtained in this Comparative Example was measured or calculated for the adhesion amount of the surface treatment layer, the proportion of the integral value of the proton peaks attributed to the benzene ring with respect to the integral value of all proton peaks as measured by ¹H-NMR, the texture, and the impregnability of the matrix resin in exactly the same manner as in Example 1, and the processability was evaluated. Furthermore, the laminated board obtained in this Comparative Example was measured for the whitening distance in exactly the same manner as in Example 1. The results are shown in Table 2.

TABLE 1

| | | | Reference | | | | | | Reference | |
|---|---|---|---|---|---|---|---|---|---|---|
| | | | Example 1 | Example 1 | Example 2 | Example 3 | Example 4 | Example 5 | Example 2 | Example 6 |
| Treatment | Glass composition | | Low | Low | Low | Low | Low | Low | Low | Low |
| conditions | | | dielectric | dielectric | dielectric | dielectric | dielectric | dielectric | dielectric | dielectric |
| | | | glass | glass | glass | glass | glass | glass | glass | glass |
| | Glass cloth type | | 2116 | 2116 | 2116 | 2116 | 2116 | 2116 | 2116 | 2116 |
| | Silane coupling agent | | Methacryl | Methacryl | Methacryl | Methacryl | Methacryl | Methacryl | Cationic | Cationic |
| | Emulsion resin | | Not | Applied | Applied | Applied | Applied | Applied | Not | Applied |
| | treatment | | applied | | | | | | applied | |
| | Emulsion resin type | | — | Styrene/acryl | Styrene/ | Styrene/ | Styrene/ | Styrene/ | — | Styrene |
| | | | | | butadiene | acryl | acryl | acryl | | /acryl |
| | Styrene composition | | — | 75 | Not | 70 | 74 | 81 | — | 75 |
| | content ratio of | | | | known | | | | | |
| | emulsion resin | | | | | | | | | |
| | Glass transition | | — | 35 | 28 | 35 | 35 | 50 | — | 35 |
| | temperature (Tg) (° C.) | | | | | | | | | |
| | Proportion (%) of | | 0 | 30.4 | 31.9 | 35.2 | 37.2 | 41.6 | 0 | 30.6 |
| | peak derived from | | | | | | | | | |
| | benzene ring | | | | | | | | | |
| | Adhesion amount (%) | | 0.40 | 1.68 | 1.93 | 1.88 | 1.92 | 1.67 | 0.47 | 1.72 |
| Evaluation | Cantilever | | 136 | 127 | 125 | 120 | 121 | 127 | 124 | 120 |
| results | measurement value | | | | | | | | | |
| | (texture) (mm) | | | | | | | | | |
| | Processability | | ◯ | ◯ | ◯ | ◯ | ◯ | ◯ | ◯ | ◯ |
| | Impregnability (min) | | 3.5 | 5.8 | 5.5 | 5.5 | 5.3 | 5.8 | 4.5 | 5.5 |
| | Whitening | Measured | 345.3 | 151.9 | 155.4 | 165.7 | 158.8 | 169.2 | 535.2 | 458.3 |
| | distance | value | | | | | | | | |
| | | (μm) | | | | | | | | |
| | | Index | 100 | 44 | 45 | 48 | 46 | 49 | 100 | 86 |
| | | relative to | | | | | | | | |
| | | Reference | | | | | | | | |
| | | Example | | | | | | | | |

Proportion (%) of peak derived from benzene ring: proportion (%) of peak derived from benzene ring to total integral value as measured by ¹H-NMR
Silane coupling agent
methacryl: 3-methacryloxypropyltrimethoxysilane
cationic: N-(vinylbenzyl)-2-aminoethyl-3-aminopropyltrimethoxysilane hydrochloride

TABLE 2

| | | | Comparative | Comparative | Comparative | Comparative | Comparative | Comparative | Comparative |
|---|---|---|---|---|---|---|---|---|---|
| | | | Example 1 | Example 2 | Example 3 | Example 4 | Example 5 | Example 6 | Example 7 |
| Treatment | Glass composition | | Low | Low | Low | Low | Low | Low | Low |
| conditions | | | dielectric | dielectric | dielectric | dielectric | dielectric | dielectric | dielectric |
| | | | glass | glass | glass | glass | glass | glass | glass |
| | Glass cloth type | | 2116 | 2116 | 2116 | 2116 | 2116 | 2116 | 2116 |
| | Silane coupling agent | | Methacryl | Methacryl | Methacryl | Methacryl | Methacryl | Methacryl | Methacryl |
| | Emulsion resin | | Applied | Applied | Applied | Applied | Applied | Not applied | Not applied |
| | treatment | | | | | | | | |
| | Emulsion resin type | | Acryl | Styrene/acryl | Styrene/acryl | Styrene/acryl | Styrene/acryl | — | — |
| | Styrene composition | | 0 | 40 | 54 | 93 | 88 | — | — |
| | content ratio of | | | | | | | | |
| | emulsion resin | | | | | | | | |
| | Glass transition | | 35 | 35 | 35 | 80 | 65 | — | — |
| | temperature (Tg) | | | | | | | | |
| | (° C.) | | | | | | | | |
| | Proportion (%) of | | 0 | 20.2 | 24.5 | 51.2 | 54.4 | 0 | 0 |
| | peak derived from | | | | | | | | |
| | benzene ring | | | | | | | | |
| | Adhesion amount | | 1.92 | 2.22 | 1.92 | 1.76 | 1.67 | 2.38 | 3.66 |
| | (%) | | | | | | | | |
| Evaluation | Cantilever | | 110 | 115 | 108 | 130 | 132 | 135 | 134 |
| results | measurement value | | | | | | | | |
| | (texture) (mm) | | | | | | | | |
| | Processability | | X | Δ | X | ◯ | ◯ | ◯ | ◯ |
| | Impregnability (min) | | 7.5 | 7.8 | 6.3 | 6.5 | 6.3 | 8.8 | 11.0 |
| | Whitening | Measured | 241.7 | 207.2 | 196.8 | 220.3 | 209.9 | 452.3 | 493.8 |
| | distance | value | | | | | | | |
| | | (μm) | | | | | | | |
| | | Index | 70 | 60 | 57 | 64 | 61 | 131 | 143 |
| | | relative to | | | | | | | |
| | | Reference | | | | | | | |
| | | Example | | | | | | | |

Proportion (%) of peak derived from benzene ring: proportion (%) of peak derived from benzene ring to total integral value
as measured by ¹H-NMR
Silane coupling agent
methacryl: 3-methacryloxypropyltrimethoxysilane

From Table 1, it is clearly shown that, according to the surface-treated glass clothes of Examples 1 to 6, in which the surface treatment layer contains the silane coupling agent and the resin for surface treatment containing a structural unit derived from a styrene-based monomer and having an integral value of a proton peak attributed to a benzene ring that falls within a range of 28 to 46% of the integral value of all proton peaks, as measured by ¹H-NMR, excellent adhesiveness between the glass fibers and the matrix resin can be obtained, and even when the adhesion amount of the surface treatment layer is increased to 0.8% by mass or more, the impregnability of the matrix resin to the glass fibers is not impaired, and excessive hardening of the texture does not occur, and excellent processability during manufacturing prepreg can be achieved.

On the other hand, it is clearly shown from Table 2 that, according to the surface-treated glass cloth of Comparative Example 1, in which the surface treatment layer does not contain a structural unit derived from a styrene-based monomer and contains a resin for surface treatment with an integral value of the proton peaks attributed to the benzene ring that is 0, as measured by ¹H-NMR, and the surface-treated glass cloths of Comparative Examples 2 and 3, in which the integral value of the proton peaks attributed to the benzene ring was less than 28% of the integral value of all proton peaks, as measured by ¹H-NMR, the texture was hardened and excellent processability could not be achieved, and not only the impregnability of the matrix resin to the glass fibers of the surface-treated glass cloths was impaired, but also the adhesiveness of the matrix resin to the surface-treated glass cloths was inferior compared to the surface-treated glass cloths of Examples 1 to 6.

In addition, it is clearly shown from Table 2 that, according to the surface-treated glass cloths of Comparative Examples 4 and 5, in which the integral value of the proton peaks attributed to the benzene ring was more than 46% of the integral value of all proton peaks, as measured by ¹H-NMR, the impregnability of the matrix resin to the glass fibers of the surface-treated glass cloths was impaired, and the adhesiveness of the matrix resin to the surface-treated glass cloths was inferior compared to the surface-treated glass cloths of Examples 1 to 6.

Furthermore, it is clearly shown from Table 2 that, according to the surface-treated glass cloths of Comparative Examples 6 and 7, in which the solid content of the silane coupling agent in the silane coupling agent treatment solution was increased while the treatment of immersing the glass cloth in the emulsion resin treatment solution was not applied, the impregnability of the matrix resin to the glass fibers of the surface-treated glass cloths was impaired, and the adhesiveness of the matrix resin to the surface-treated glass cloths was significantly inferior compared to the surface-treated glass cloths of Examples 1 to 6.

1. A surface-treated glass cloth comprising a surface treatment layer on a surface thereof, wherein
the surface treatment layer contains a silane coupling agent and a resin for surface treatment, and the resin for surface treatment contains a structural unit derived from a styrene-based monomer and has an integral value of a proton peak attributed to a benzene ring that falls within a range of 28 to 46% of an integral value of all proton peaks, as measured by ¹H-NMR.

2. The surface-treated glass cloth according to claim 1, wherein the silane coupling agent is a methacrylic silane.

3. The surface-treated glass cloth according to claim 1, wherein the styrene-based monomer is one or more monomers selected from a styrene-based monomer represented by following general formula (1): 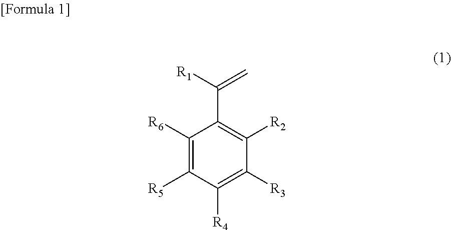
wherein, R₁ represents hydrogen or an alkyl group having 1 to 2 carbon atoms, and R₂ to R₆ each independently represent hydrogen and a halogen atom, an alkyl group, an alkenyl group, an alkynyl group, or an aryl group, which may contain a heteroatom.

4. The surface-treated glass cloth according to claim 1, wherein the surface treatment layer consists of a first surface treatment layer containing the silane coupling agent and a second surface treatment layer containing the resin for surface treatment.

5. The surface-treated glass cloth according to claim 1, wherein an adhesion amount of the surface treatment layer is in a range of 0.8 to 5.0% by mass with respect to a total amount of the surface-treated glass cloth.

6. The surface-treated glass cloth according to claim 1, wherein a dielectric loss tangent at a measurement frequency of 10 GHz is in a range of 0.0001 to 0.0040.

7. A prepreg comprising the surface-treated glass cloth according to am claim 1.

8. A printed wiring board comprising the surface-treated glass cloth according to claim 1.
